(19) United States
(12) Patent Application Publication
(10) Pub. No.: US 2025/0033219 A1
(43) Pub. Date: Jan. 30, 2025

(54) Transfer Teaching Method and Substrate Processing System

(71) Applicant: Tokyo Electron Limited, Tokyo (JP)

(72) Inventor: Toshiaki Kodama, Yamanashi (JP)

(21) Appl. No.: 18/773,282

(22) Filed: Jul. 15, 2024

(30) Foreign Application Priority Data
Jul. 28, 2023 (JP) 2023-123109

(51) Int. Cl. B25J 11/00; B25J 9/16

(52) U.S. Cl. CPC B25J 11/0095; B25J 9/1664

(57) ABSTRACT

A transfer teaching method for teaching a transfer position of a transfer device to transfer a transfer object using the transfer device is provided. The method comprises (A) moving the transfer device with respect to the transfer object placed on a placing location and detecting the transfer object using a sensor of the transfer device, (B) calculating a position of the transfer object based on the detected transfer object, and (C) setting the transfer position based on the calculated position of the transfer object.

### CROSS-REFERENCE TO RELATED APPLICATIONS

This application claims priority to Japanese Patent Application No. 2023-123109 filed on Jul. 28, 2023, the entire contents of which are incorporated herein by reference.

### TECHNICAL FIELD

The present disclosure relates to a transfer teaching method and a substrate processing system.

### BACKGROUND

Japanese Laid-open Patent Publication No. 2022-132087 discloses a substrate processing system (transfer system) for transferring a substrate, which is a transfer object, using a vacuum transfer robot (transfer device) of a vacuum transfer module, and processing the substrate in a process module.

In the substrate processing system, a central position of a placing location (e.g., a placing table of a processing module or the like) where the substrate is received and delivered is taught to the transfer device during setting or maintenance. Accordingly, the substrate processing system can accurately move the transfer device based on the taught position during an operation of actually transferring the substrate and processing the substrate.

### SUMMARY

The present disclosure provides a technique capable of efficiently teaching a transfer position of a transfer device and improving the transfer accuracy of a transfer object.

According to one aspect of the present disclosure, a transfer teaching method for teaching a transfer position of a transfer device to transfer a transfer object using the transfer device comprises (A) moving the transfer device with respect to the transfer object placed on a placing location and detecting the transfer object using a sensor of the transfer device, (B) calculating a position of the transfer object based on the detected transfer object, and (C) setting the transfer position based on the calculated position of the transfer object.

### BRIEF DESCRIPTION OF THE DRAWINGS

FIG. 1 is a schematic plan view showing an example of an overall configuration of a substrate processing system according to an embodiment.

FIG. 2A shows a path placing part according to an embodiment.

FIG. 2B show a path placing part according to a first modification.

FIG. 2C shows a path placing part according to a second modification.

FIG. 3 is an enlarged plan view showing a substrate and a fork of a vacuum transfer device.

FIG. 4 is a plan view showing a route for transferring a substrate to a processing module in a rear region.

FIG. 5A is a plan view showing a state in which a substrate is placed on the path placing part by a first transfer device.

FIG. 5B is a side view showing an operation of scanning a substrate by a second transfer device.

FIG. 5C is a plan view showing an operation of scanning a substrate by the second transfer device.

FIG. 6 is a flowchart showing a transfer teaching method for the second transfer device.

FIG. 7A is a plan view showing an operation of retreating the second transfer device in the transfer teaching method.

FIG. 7B is a plan view showing an operation of correcting the second transfer device in the transfer teaching method.

FIG. 7C is a plan view showing rescanning by the second transfer device in the transfer teaching method.

### DETAILED DESCRIPTION

Hereinafter, embodiments of the present disclosure will be described with reference to the accompanying drawings. Like reference numerals will be given to like parts throughout the drawings, redundant description thereof may be omitted.

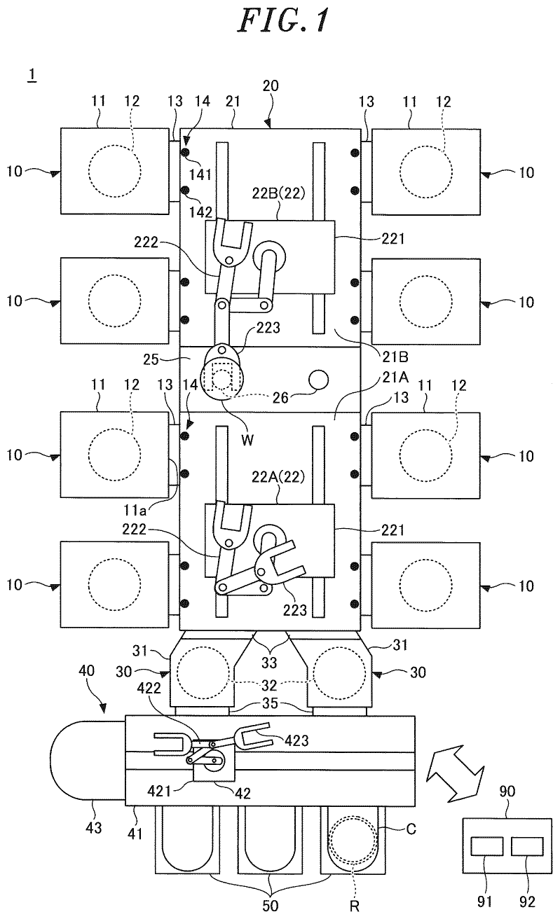

FIG. 1 is a schematic plan view showing an example of an overall configuration of a substrate processing system 1 according to an embodiment. As shown in FIG. 1, the substrate processing system 1 is a multi-chamber type semiconductor manufacturing apparatus including a plurality of processing modules 10. Each processing module 10 performs substrate processing such as film formation, etching, cleaning, or the like on a substrate W that is an example of a transfer object. The substrate processing system 1 further includes, in addition to the processing modules 10, a vacuum transfer module 20, a plurality of load-lock modules 30, an atmospheric transfer module 40, load ports 50, and a controller 90.

The substrate W is loaded and unloaded between each processing module 10 and the vacuum transfer module 20. Each processing module 10 performs substrate processing on the substrate W accommodated therein. The plurality of processing modules 10 of the substrate processing system 1 may perform the same processing. Alternatively, some of them or all of them may perform different types of processing. Further, the substrate processing system 1 may be configured to perform plasma processing in some or all of the processing modules 10.

Specifically, each processing module 10 includes a processing chamber 11 accommodating a substrate W, and a placing table 12 on which the substrate W is placed in the processing chamber 11. The placing table 12 is provided with lifters (for example, a plurality of pins) (not shown) that raise and lower the substrate W, and receives and transfers the substrate W in cooperation with a vacuum transfer device 22 to be described later.

Further, each processing module 10 includes a connection part 13 that connects the processing chamber 11 and the vacuum transfer module 20, and a processing module-side sensor 14 that detects the substrate W. The connection part 13 has therein a gate valve (not shown) that opens and closes an opening 11a of the processing chamber 11. In each processing module 10, the substrate W can be transferred to the processing chamber 11 via the connection part 13 by opening the gate valve, and the pressure in the processing chamber 11 can be reduced to an appropriate vacuum atmosphere by closing the gate valve.

The processing module-side sensor 14 detects the outer edge of the substrate W when the substrate W is transferred between each processing module 10 and the vacuum transfer module 20, and transmits the detection information to the controller 90. The controller 90 can calculate the center position of the substrate W based on the detection information of the processing module-side sensor 14, and can also recognize the deviation of the center position of the substrate W that is being transferred to the vacuum transfer device 22. The processing module-side sensor 14 is disposed, e.g., at a position adjacent to the opening 11a of each processing module 10 in the vacuum transfer module 20. Further, the processing module-side sensor 14 may be provided inside the connection part 13 or may be provided at a position adjacent to the opening 11a in the processing module 10.

The processing module-side sensor 14 has two detectors 141 and 142 for detecting whether or not the substrate W exists. For example, each of the detectors 141 and 142 includes a light emitting part (not shown) for emitting measurement light, and a light receiving part (not shown) for receiving light from the light emitting part with a route through which the substrate W passes interposed therebetween. The detectors 141 and 142 detect the presence of the substrate W when the measurement light is blocked by the passage of the substrate W. The two detectors 141 and 142 are arranged in a direction parallel to the opening 11a, and they are disposed such that the distance therebetween becomes shorter than the diameter of the substrate W. The principle in which the position of the substrate W is calculated by the detection of the processing module-side sensor 14 is the same as that of fork-side sensors 227 of the vacuum transfer device 22 to be described later, and will be described in detail later.

The vacuum transfer module 20 of the substrate processing system 1 is depressurized to a vacuum atmosphere. The vacuum transfer module 20 includes a transfer chamber 21 connected to the respective processing modules 10 and the plurality of load-lock modules 30, and a vacuum transfer device 22 that transfers the substrate W in the transfer chamber 21.

Further, in the vacuum transfer module 20 according to the embodiment, the inner space of the transfer chamber 21 is divided into three transfer regions along the longitudinal direction. Specifically, the vacuum transfer module 20 includes a front region 21A, a path region 25, and a rear region 21B in that order in a direction away from a position adjacent to the load-lock modules 30. However, the front region 21A, the path region 25, and the rear region 21B are not separated by partition walls or the like, and spatially communicate with each other in the transfer chamber 21.

The front region 21A is a first region of the vacuum transfer module 20 that transfers the substrate W between a plurality of (four in FIG. 1) processing modules 10, the path region 25, and the plurality of load-lock modules 30. A first transfer device 22A, which is a vacuum transfer device 22, is installed in the front region 21A. Further, the number of processing modules 10 connected to the front region 21A is not limited to four, and may be set to any number.

The rear region 21B is a second region of the vacuum transfer module 20 that transfers the substrate W between a plurality of (four in FIG. 1) processing modules 10 and the path region 25. A second transfer device 22B, which is a vacuum transfer device 22, is installed in the rear region 21B. Further, that the number of processing modules 10 connected to the rear region 21B is not limited to four, and may be set to any number. Further, the vacuum transfer device 22 does not necessarily include three transfer areas (the front region 21A, the path region 25, the rear region 21B), and may include four or more regions. For example, the vacuum transfer module 20 may include a transfer region having the vacuum transfer device 22 on one side (the upper side in FIG. 1) of the rear region 21B via another path region 25.

The path region 25 is a placing location prepared for receiving and transferring the substrate W between the first transfer device 22A in the front region 21A and the second transfer device 22B in the rear region 21B. Specifically, the path region 25 has a plurality of (two in FIG. 1) path placing parts 26 on which the substrate W is temporarily placed. When the substrate W held by the first transfer device 22A is placed on the path placing part 26 and the second transfer device 22B holds the substrate W on the path placing part 26, the transfer of the substrate W from the first transfer device 11A to the second transfer device 22B is completed. On the contrary, when the substrate W held by the second transfer device 22B is placed on the path placing part 26 and the first transfer device 22A holds the substrate W on the path placing part 26, the transfer of the substrate W from the second transfer device 22B to the first transfer device 22A is completed.

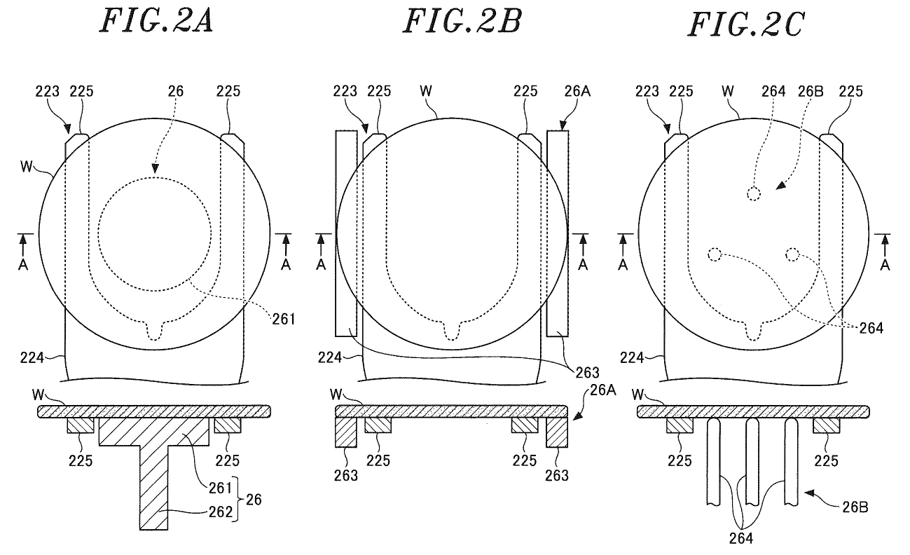

FIG. 2A shows the path placing part 26 according to the embodiment. FIG. 2B shows a path placing part 26A according to a first modification. FIG. 2C shows a path placing part 26B according to a second modification. Further, in FIGS. 2A to 2C, upper diagrams are plan views, and lower diagrams are cross-sectional views taken along the line A-A of the upper diagrams.

As shown in FIG. 2A, the path placing part 26 according to the embodiment includes a placing table 261 having a perfect circular shape in plan view, and a support 262 connected to the bottom surface of the placing table 261. The placing table 261 is a circular plate having a flat upper surface and a diameter smaller than that of the substrate W. By placing the central region of the substrate W on the upper surface of the placing table 261, the path placing part 26 can stably support the substrate W.

However, in the substrate processing system 1, the configuration of the path placing part 26 is not particularly limited, and may be variously modified. For example, the path placing part 26A according to the first modification shown in FIG. 2B has a pair of shelf boards 263 for supporting the outer edge of the substrate W instead of the placing table 261 for supporting the central region of the substrate W shown in FIG. 2A. The pair of shelf boards 263 extend parallel to each other, and are spaced apart from each other by a distance shorter than the diameter of the substrate W. Also in this case, the pair of shelf boards 263 can stably support the outer edge of the substrate W.

Further, for example, the path placing part 26B according to the second modification shown in FIG. 2C has a plurality of (three in FIG. 2C) support pins 264 for supporting the central region of the substrate W. The support pins 264 are provided, e.g., at positions constituting the apexes of an equilateral triangle to be located at the same height. Accordingly, the support pins 264 can stably support the bottom surface of the central region of the substrate W. Further, the support pins 264 are configured to be raised and lowered relative to a floor (not shown) from which the support pins 264 protrude, and may be raised to receive the substrate W when the substrate W reaches a position thereabove and lowered in reverse to deliver the substrate W. The path placing part 26 shown in FIG. 2A or the path placing part 26A shown in FIG. 2B may have such a raising/lowering function.

Referring back to FIG. 1, in the vacuum transfer module 20, two path placing parts 26 are arranged side by side in the lateral direction at an intermediate position in the longitudinal direction of the transfer chamber 21 to form the path region 25, thereby dividing the front region 21A and the rear region 21B. Further, in the vacuum transfer module 20, the location where the path placing parts 26 are disposed in the transfer chamber 21 may be simply set to the path region 25, but the path region 25 may be spatially partitioned from the front region 21A and the rear region 21B by a partition wall (not shown) or the like. In this case, an opening and a gate valve for opening and closing the opening are preferably formed in the partition wall. Further, the vacuum transfer module 20 may include a plurality of transfer regions by connecting the plurality of transfer chambers 21 (the transfer chamber having the front region 21A, the transfer chamber having the path region 25, and the transfer chamber having the rear region 21B).

The plurality of vacuum transfer devices 22 (the first transfer device 22A, and the second transfer device 22B) of the vacuum transfer module 20 are configured to operate independently. Each vacuum transfer device 22 has a base 221 that is movable in the longitudinal direction of the transfer chamber 21, a plurality of arms 222 that can rotate, extend and contract, and move up and down with respect to the base 221, and a fork (end effector) 223 disposed at the arm 222 on the distal end side. Although FIG. 1 illustrates the vacuum transfer device 22 having two forks 223, the vacuum transfer device 22 is not limited thereto, and may have a configuration including one or three or more forks 223.

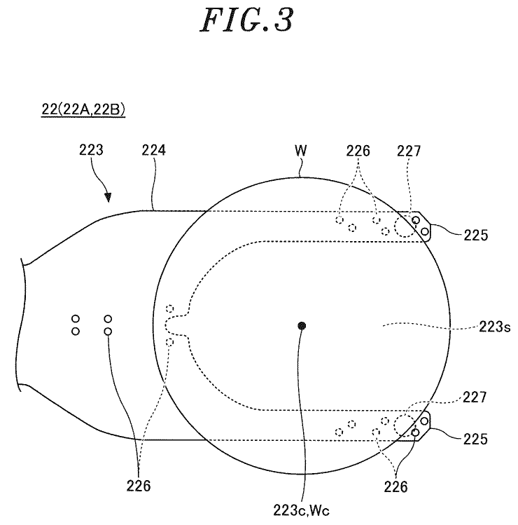

FIG. 3 is an enlarged plan view showing the substrate W and the fork 223 of the vacuum transfer device 22. As shown in FIG. 3, the vacuum transfer device 22 supports the substrate W on the upper surface of the fork 223 and transfers the substrate W by appropriately operating the base 221 and the arms 222 (see FIG. 1).

The fork 223 has a base plate portion 224 connected to the arm 222 on the distal end side, and a pair of support plate portions 225 extending while being branched from the base plate portion 224. The base plate portion 224 and the pair of support plate portions 225 are integrally molded with each other and continuous in the horizontal direction, thereby forming a U-shape in plan view. The pair of support plate portions 225 are parallel to each other, and have the same length. The gap between the pair of support plate portions 225 is larger than the diameter of the placing table 261 of the path placing part 26 described above (see also FIG. 2A). The fork 223 has a concave space 223s surrounded by the base plate part 224 and the pair of support plate portions 225. The concave space 223s is opened at the tip ends (extension ends) of the pair of support plate portions 225.

The fork 223 configured as described above can be raised and lowered relative to the placing table 261 of the path placing part 26 through the concave space 223s, for example. Therefore, the vacuum transfer device 22 can place the substrate W directly above the placing table 261 using the fork 223, and can place the substrate W on the upper surface of the placing table 261 by lowering the fork 223. On the contrary, the vacuum transfer device 22 can move the fork 223 to a position below the placing table 261 on which the substrate W is placed, and can receive the substrate W on the fork 223 by raising the fork 223.

Further, the fork 223 has a plurality of pads 226 on the upper surfaces of the base plate portion 224 and the support plate portion 225. For example, the plurality of pads 226 are disposed at intermediate positions in the width direction of the base plate portion 224, and are also disposed on the tip end sides of the pair of support plate portions 225 to directly support the positions of the substrate W in three directions. The plurality of pads 226 may be made of a material (such as an elastomer or the like) having appropriate frictional force and elasticity. Further, the fork 223 may have a holding device such as a suction mechanism, an electrostatic attraction mechanism, or a mechanical locking mechanism for holding the substrate W using the plurality of pads 226 (or instead of the plurality of pads 226).

In the case of supporting the substrate W with the fork 223, the vacuum transfer device 22 moves the fork 223 such that a center position Wc of the substrate W coincides with a reference position 223c that is preset at the fork 223. Further, the position where the fork 223 of the vacuum transfer device 22 moves to support or place the substrate W corresponds to “transfer position” in the embodiment. The vacuum transfer device 22 can stably support the substrate W by moving the fork 223 such that the reference position 223c coincides with the transfer position and bringing the fork 223 into contact with the substrate W.

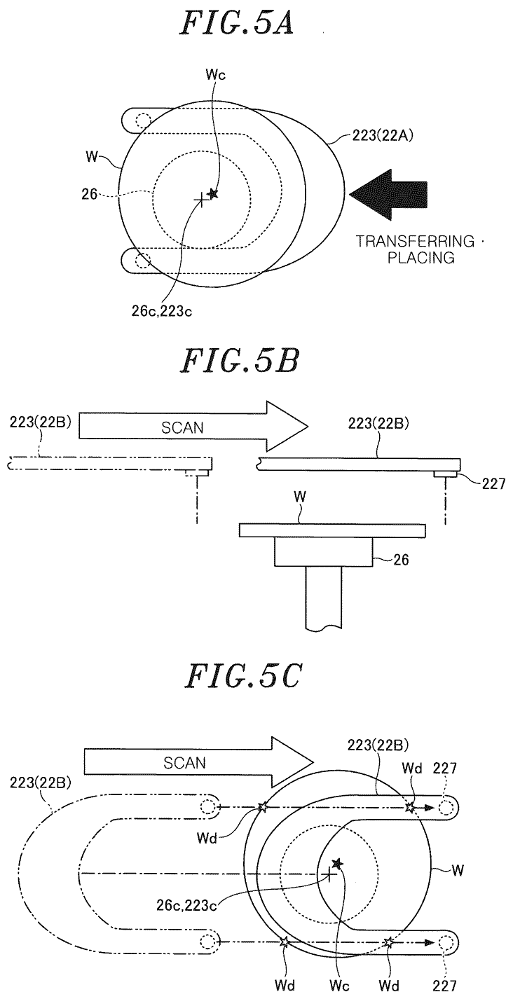

The fork 223 according to the embodiment has the plurality of (two in FIG. 2) fork-side sensors 227 for detecting the substrate W as a transfer object on the surface (bottom surface) opposite to the surface for supporting the substrate W. Specifically, the fork-side sensors 227 are disposed near the extension ends (tip ends of the fork 223) of the pair of support plate portions 225, and have detectors for detecting an object disposed below (opposed to) the fork 223 in the vertical direction (see also FIG. 5B). Each fork-side sensor 227 is connected to the controller 90 to be communicable therewith, performs detection under the control of the controller 90, and transmits the detection information to the controller 90.

For example, each fork-side sensor 227 according to the embodiment is a displacement sensor for optically measuring the distance from the fork 223 to the object. In this case, each fork-side sensor 227 has a light emitting part and a light receiving part included in a detector, and measures the distance to the object based on the light intensity or wavelength of the detection light emitted by the light emitting part and reflected by the object. Therefore, when the detection of the fork-side sensors 227 is continued while the fork 223 is moving above the substrate W, the fork-side sensors 227 can detect a change in the distance at the outer edge of the substrate W, and the controller 90 can recognize the outer edge of the substrate W based on the detection information. Further, the controller 90 can calculate the center position of the substrate W based on detection information at a plurality of locations on the outer edge of the substrate W using a calculation method to be described later.

Further, the type of the fork-side sensors 227 is not particularly limited as long as the substrate processing system 1 can acquire the center position of the substrate W to be transferred. The fork-side sensor 227 may also be an on-off sensor that detects the outer edge of the substrate W by transmitting or blocking detection light, a capacitance sensor that detects a change in a capacitance when it passes through a position above the substrate W, or the like. Alternatively, the fork-side sensor 227 may be an infrared sensor, an ultrasonic sensor, a radar, a camera, or the like. Further, in the substrate processing system 1, the position and number of the fork-side sensors 227 installed at the fork 223 are not particularly limited. For example, if one camera is provided as the fork-side sensor 227 and images a part of the outer edge of the substrate W, it is possible to calculate the center position of the substrate W.

Referring back to FIG. 1, the vacuum transfer device 22 (the first transfer device 22A and the second transfer device 22B) transfers the substrate W from an appropriate load-lock module 30 to an appropriate processing module 10 under the control of the controller 90. Further, the vacuum transfer device 22 transfers the substrate W from an appropriate processing module 10 to an appropriate load-lock module 30 under the control of the controller 90. Further, the vacuum transfer device 22 may transfer the substrate W between two processing modules 10.

The two load-lock modules 30 of the substrate processing system 1 are disposed between the vacuum transfer module 20 and the atmospheric transfer module 40, and an inner atmosphere thereof is switched between an atmospheric atmosphere and a vacuum atmosphere. Specifically, each load-lock module 30 includes the chamber 31 accommodating a substrate W, and a placing table 32 for placing the substrate W thereon in the chamber 31. For example, the placing table 32 has a groove (not shown) into which the fork 223 of the first transfer device 22A and a fork 423 of an atmospheric transfer device 42 (to be described later) can enter, and the substrate W is received and delivered by moving the forks 223 and 423 back and forth and up and down. Further, the placing table 32 may include lifters, similarly to the placing table 12 of the processing module 10.

Further, each load-lock module 30 includes a connection part 33 on the vacuum transfer module 20 side and a connection part 35 on the atmospheric transfer module 40 side. The connection parts 33 and 35 have therein gate valves (not shown) for opening and closing the opening of the chamber 31. Each load-lock module 30 communicates with the vacuum transfer module 20 by opening the gate valve of the connection part 33 in a vacuum atmosphere. Further, each load-lock module 30 communicates with the atmospheric transfer module 40 by opening the gate valve of the connection part 35 in an atmospheric state.

The inner atmosphere of the atmospheric transfer module 40 of the substrate processing system 1 is maintained in an atmospheric atmosphere. The atmospheric transfer module 40 includes a transfer chamber 41 connected to the load-lock modules 30, and an atmospheric transfer device 42 for transferring the substrate W in the transfer chamber 41. Further, in the atmospheric transfer module 40, downflow of clean air may be generated in the transfer chamber 41. In addition, an aligner 43 for aligning the substrate W is disposed on the lateral side of the atmospheric transfer module 40.

Further, the plurality of load ports 50 are provided on the wall surface of the atmospheric transfer module 40. A carrier C containing a substrate W or an empty carrier C is attached to each load port 50. The carrier C may be, e.g., a front opening unified pod (FOUP) or the like. Further, a carrier C accommodating a ring R (a focus ring, an edge ring, or the like) that is an example of a transfer object may be attached to each load port 50. The ring R is disposed around the substrate W on the placing table 12 of the processing module 10.

Similar to the vacuum transfer device 22, the atmospheric transfer device 42 includes a base 421 that is movable in the longitudinal direction of the transfer chamber 41, a plurality of arms 422 that can rotate, extend and contract, and move up and down with respect to the base 421, and a fork (end effector) 423 disposed at the arm 422 on the distal end side. The atmospheric transfer device 42 supports the substrate W on the upper surface of the fork 423, and transfers the substrate W by appropriately operating the base 421 and the arms 422. Although FIG. 1 illustrates the atmospheric transfer device 42 including two forks 423, the present disclosure is not limited thereto, and the atmospheric transfer device 42 may have a configuration including one or three or more forks 423.

The atmospheric transfer device 42 transfers the substrate W between each load-lock module 30 and the atmospheric transfer module 40 by opening and closing the gate valve of each connection part 35. Further, the atmospheric transfer device 42 transfers the substrate W between the aligner 43 and the atmospheric transfer module 40. Further, the atmospheric transfer device 42 transfers the substrate W between each carrier C attached to each load port 50 and the atmospheric transfer module 40.

The controller 90 is a computer including a processor 91, a memory 92, an input/output interface, and a communication interface (not shown). The processor 91 is combination of one or more of a central processing unit (CPU), a graphics processing unit (GPU), an application specific integrated circuit (ASIC), a field-programmable gate array (FPGA), a circuit including a plurality of discrete semiconductors, and the like, and executes the program stored in the memory 92. The memory 92 includes a main storage device such as a semiconductor memory, and an auxiliary storage device such as a disk or a semiconductor memory (flash memory).

For example, the controller 90 controls the atmospheric transfer device 42 to transfer an unprocessed substrate W of the carrier C attached to the load port 50 to the aligner 43 so that the substrate W can be aligned, and to transfer the substrate W of the aligner 43 to one of the load-lock modules 30. After the load-lock module 30 containing the substrate W is depressurized, the controller 90 controls the vacuum transfer device 22 to take out the substrate W and transfers the substrate W to one of the processing modules 10 via the vacuum transfer module 20. Thereafter, the controller 90 performs substrate processing in each processing module 10 into which the substrate W is loaded. After the substrate processing, the controller 90 transfers the substrate W of one processing module 10 to the carrier C for accommodating a processed substrate W in a reverse order of the above-described sequence.

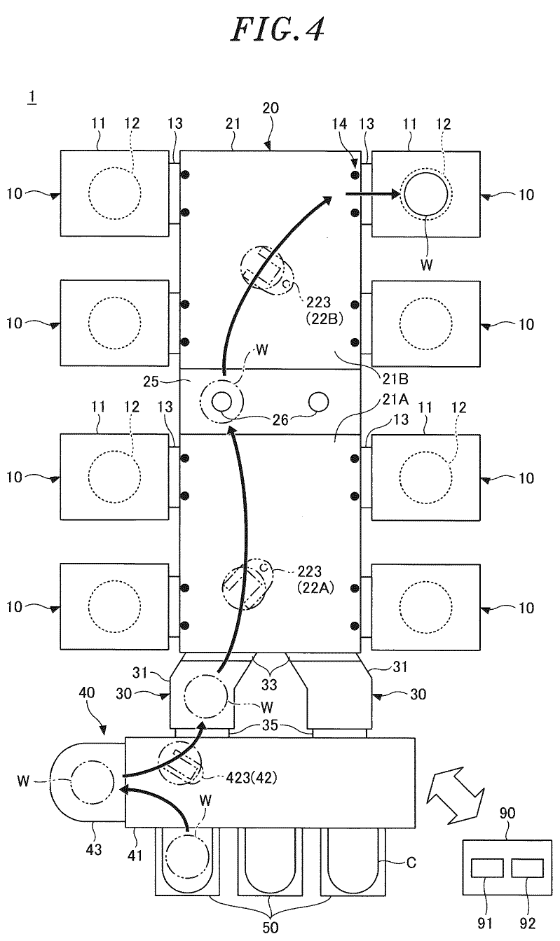

FIG. 4 is a plan view showing a route for transferring the substrate W to the processing module 10 in the rear region 21B. As shown in FIG. 4, in the substrate processing system 1, the substrate W can be transferred from the load port 50 of the atmospheric transfer module 40 to a desired processing module 10 in the rear region 21B, and can be subjected to substrate processing in the processing module 10. In this case, the controller 90 controls each of the atmospheric transfer device 42, the first transfer device 22A, and the second transfer device 22B to transfer the substrate W.

Specifically, the controller 90 controls the first transfer device 22A to take out the substrate W, which has been transferred from the aligner 43 to one load-lock module 30 by the atmospheric transfer device 42, and transfer the substrate W into the front region 21A. Then, the controller 90 controls the first transfer device 22A to place the substrate W on one path placing part 26 of the path region 25. Further, the controller 90 controls the second transfer device 22B to take out the substrate W from the path placing part 26, transfer the substrate W into the rear region 21B, and load the substrate W into a desired processing module 10.

Here, in the substrate processing system 1, there are errors that occur during installation in a factory, dimensional errors of structures, machine differences of devices, and the like. Such errors cause deviation with respect to a preset transfer position, which deteriorates the transfer accuracy of the substrate W. Therefore, the substrate processing system 1 performs a teaching process for teaching the transfer positions of the vacuum transfer device 22 (the first transfer device 22A and the second transfer device 22B) and the atmospheric transfer device 42 during system setting, maintenance, or the like.

For example, in the case of teaching the transfer position of the first path placing part 26 to the second transfer device 22B, in a conventional teaching process, the fork-side sensors 227 detect the outer edge of the placing table 261 by raising and lowering the fork 223 in the vertical direction near one first path placing part 26 and sliding the fork 223 in the horizontal direction, and the center position of the placing table 261 is calculated based on the detection information. In the case of actually receiving the substrate W on the path placing part 26 with the second transfer device 22B, the fork 223 is operated such that the calculated center position of the placing table 261 coincides with the reference position 223c of the fork 223, which makes it possible to accurately support the substrate W. Since, however, the controller 90 performs the same teaching process in the respective processing modules 10 and the respective path placing parts 26, and operates the second transfer device 22B in various manners for each teaching process, drawbacks such as an increase in a time required for the teaching process, and the like occur.

Further, in the substrate processing system 1, the center position Wc of the substrate W is likely to be deviated with respect to the center position 26c of the path placing part 26, and the deviation amount may become large. This is because the atmospheric transfer device 42 loads the substrate W into the load-lock module 30, and the first transfer device 22A transfers the substrate W from the load-lock module 30 to the path placing part 26, so that the errors of the atmospheric transfer device 42 and the first transfer device 22A are applied to the path placing part 26. In other words, in the vacuum transfer module 20 including the plurality of vacuum transfer devices 22, the deviation of the substrate W tends to become large in the vacuum transfer device 22 (the second transfer device 22B) spaced apart from the load-lock modules 30.

In the substrate processing system 1 according to the embodiment, in the process of teaching the second transfer device 22B at the time of receiving the substrate W from the path placing part 26, the transfer position is taught to the second transfer device 22B using the substrate W that is actually placed on the path placing part 26 by the first transfer device 22A. Accordingly, the transfer position of the second transfer device 22B can be set in response to the actual deviation of the substrate W and, thus, the transfer accuracy can be improved. Hereinafter, the principle of the transfer teaching method for teaching the transfer position using the substrate W will be described with reference to FIGS. 5A to 5C.

FIG. 5A is a plan view showing a state in which the substrate W is placed on the path placing part 26 by the first transfer device 22A. FIG. 5B is a side view showing an operation of scanning the substrate W by the second transfer device 22B. FIG. 5C is a plan view showing an operation of scanning the substrate W by the second transfer device 22B. As shown in FIG. 5A, in the case of placing the substrate W supported by the fork 223 on the path placing part 26, the first transfer device 22A may place the substrate W such that the center position Wc of the substrate W is deviated from the center position 26c of the path placing part 26. This is because the error caused by the atmospheric transfer device 42 or the error caused by the first transfer device 22A is calculated while the substrate W is being transferred to the path placing part 26, as described above.

In order to teach the transfer position at the time of receiving the substrate W on the path placing part 26 with the second transfer device 22B, the controller 90 controls the second transfer device 22B to detect (scan) the substrate W placed on the path placing part 26 in the transfer teaching method, as shown in FIG. 5B. Specifically, the controller 90 acquires the detection information of the pair of fork-side sensors 227 while sliding the second transfer device 22B linearly and horizontally at a position vertically above the substrate W. In this case, the linear movement of the second transfer device 22B is controlled such that the reference position 223c (center) of the fork 223 passes through a design position that is preset at the path placing part 26.

As shown in FIG. 5C, the fork-side sensors 227 disposed near the tip ends of the support plate portions 225 of the second transfer device 22B detect the outer edge of the substrate W while passing through a position above the substrate W. Specifically, the pair of fork-side sensors 227 transmit the timing at which a long distance is switched to a short distance and the timing at which a short distance is switched to a long distance to the controller 90 when they pass through the position above the substrate W. Further, during the scan of the second transfer device 22B, the controller 90 recognizes the position of the fork 223, i.e., the positions (three-dimensional coordinates) of the fork-side sensors 227, based on the movement of the arms 222 of the second transfer device 22B. The controller 90 associates the timing at which the fork-side sensors 227 detect information with the recognized positions of the fork-side sensors 227, thereby detecting two locations Wd (see white stars in FIG. 5C) on the outer edge of the substrate W. In other words, the controller 90 can detect four positions Wd at the outer edge of the substrate W using the pair of fork-side sensors 227.

Then, the controller 90 can calculate the center position Wc (see a black star in FIG. 5C) of the substrate W using the detected positions of the four locations Wd. For example, the controller 90 can calculate normal lines directed radially inward from the detected four locations Wd, and calculate the location where the normal lines intersect with each other as the center position of the substrate W.

Accordingly, the controller 90 can recognize the deviation (deviation amount or deviation direction) between the calculated center position of the substrate W and the center position of the placing table 261 of the path placing part 26, and also can correct the transfer position of the second transfer device 22B such that the deviation is eliminated.

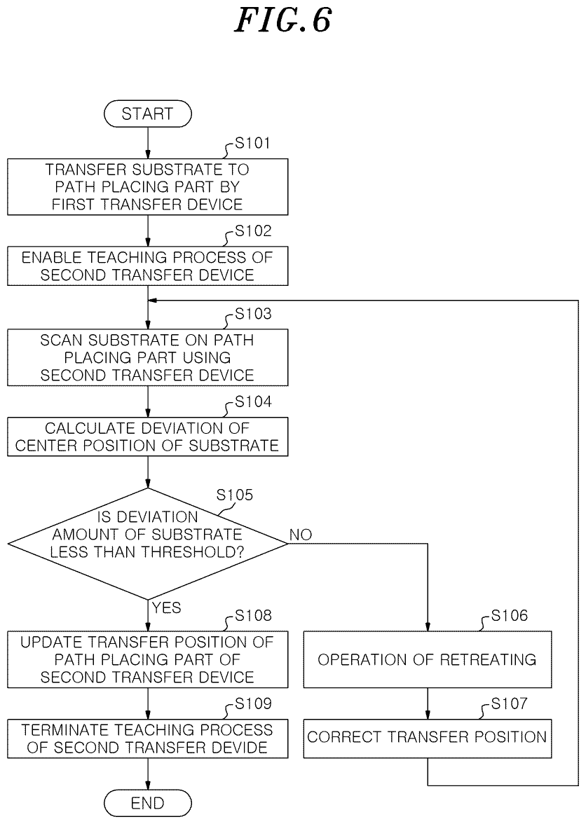

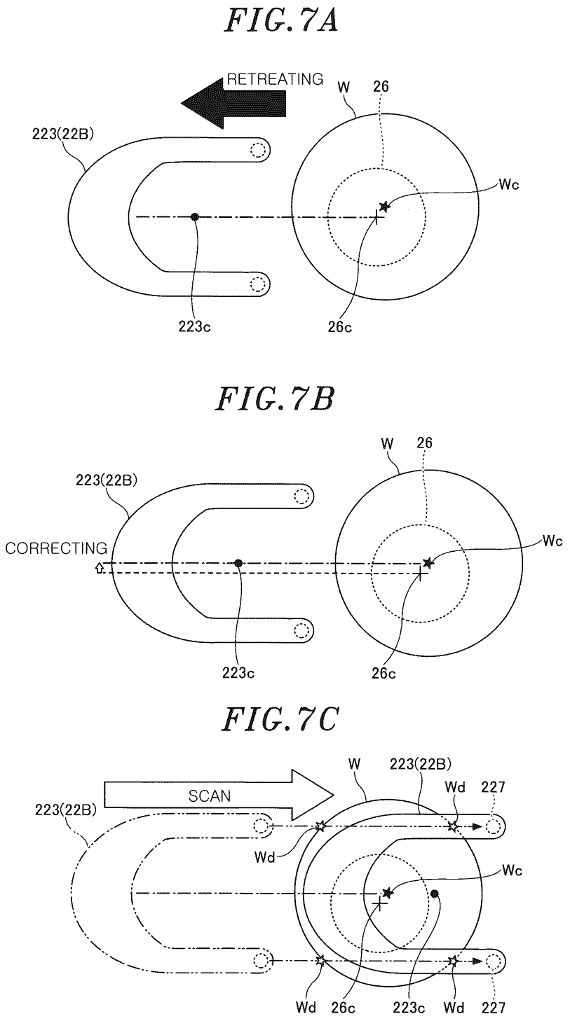

The substrate processing system 1 according to the embodiment is basically configured as described above. Hereinafter, the operation (transfer teaching method) thereof will be described with reference to FIGS. 6 and 7. FIG. 6 is a flowchart showing a transfer teaching method for the second transfer device 22B. FIG. 7A is a plan view showing an operation of retreating the second transfer device 22B in the transfer teaching method. FIG. 7B is a plan view showing an operation of correcting the second transfer device 22B in the transfer teaching method. FIG. 7C is a plan view showing rescanning by the second transfer device 22B in the transfer teaching method.

In the case of teaching the transfer position in the second transfer device 22B, the controller 90 of the substrate processing system 1 first controls the atmospheric transfer device 42 and the first transfer device 22A to transfer the substrate W, and places the substrate W on the path placing part 26 to be taught (step S101). Accordingly, the substrate W is placed on the placing table 261 of the path placing part 26 while being deviated to include the error of the atmospheric transfer device 42 and the error of the first transfer device 22A (see also FIG. 5A).

When the substrate W is placed on the path placing part 26, the controller 90 enables the mode in which the second transfer device 22B performs a teaching process (step S102). Accordingly, the controller 90 operates the second transfer device 22B to start a teaching process for correcting the transfer position based on the detection information of the fork-side sensors 227.

In the teaching process, the controller 90 operates the arms 222 of the second transfer device 22B to move the fork 223, and detects (scans) the substrate on the path placing part 26 using the fork-side sensors 227 during the movement of the fork 223 (step S103). In this case, the second transfer device 22B moves the fork 223 linearly toward a position vertically above the placing table 261 in a vertical direction and toward the center position 26c of the placing table 261 (see also FIG. 5B). Accordingly, the fork-side sensors 227 can detect the four locations Wd on the outer edge of the substrate W (see also FIG. 5C).

Then, the controller 90 acquires the detection information of the fork-side sensors 227, calculates the center position of the substrate W based on the detected positions of the four locations Wd on the substrate W, and further calculates the deviation of the center position with respect to the reference position 223c of the fork 223 (step S104). As described above, the deviation of the substrate W is calculated as the deviation direction and the deviation amount.

Next, the controller 90 compares the calculated deviation amount of the substrate W with a pre-obtained threshold, and determines whether or not the deviation amount is less than the threshold (step S105). The threshold is preferably set to a value that allows the center position Wc of the substrate W to coincide with the reference position 223c of the fork 223 and the fork 223 to stably support the substrate W. For example, the threshold is preferably set to an appropriate value within a range of 0.1 mm to 1.0 mm. The controller 90 proceeds to step S106 when the deviation amount is greater than or equal to the threshold (step S105: NO), and proceeds to step S108 when the deviation amount is less than the threshold (step S105: YES).

In step S106, the controller 90 performs an operation of retreating the fork 223 of the second transfer device 22B with respect to the substrate W placed on the path placing part 26 (see FIG. 7A).

After step S106, the controller 90 corrects the transfer position of the second transfer device 22B based on the calculated deviation direction and the calculated deviation amount (step S107). For example, the controller 90 calculates vector components in the X-axis direction and the Y-axis direction based on the deviation direction and the deviation amount. As shown in FIG. 7B, when the fork 223 of the second transfer device 22B is deviated in the X-axis direction, the reference position 223c of the fork 223 is moved to a position where the deviation amount in the X-axis direction is eliminated.

After step S107, the controller 90 returns to step S103 in FIG. 6, and repeats the same processing flow. Further, when the fork 223 of the second transfer device 22B is deviated in the Y-axis direction, the moving amount of the reference position 223c of the fork 223 may be changed to eliminate the deviation amount in the Y-axis direction in step S103. Accordingly, the second transfer device 22B can detect the outer edge of the substrate W on the path placing part 26 again using the fork-side sensors 227.

Due to the second and subsequent operations of the second transfer device 22B, the detection information detected by the fork-side sensors 227 includes the position of the outer edge of the substrate W that has been corrected from the previous detection information of the substrate W. The controller 90 calculates the center position Wc of the substrate W based on the corrected position of the outer edge of the substrate W, thereby obtaining a position where the deviation of the center position Wc of the substrate W from the reference position 223c of the fork 223 is substantially eliminated. Therefore, in step S105, the controller 90 can determine the substrate W in which the deviation amount is less than the threshold.

Further, if the deviation amount is greater than or equal to the threshold even after the second and subsequent processing flows are performed, the process of performing steps S106 and S107 again and returning to step S103 is repeated. Further, if the deviation amount of the substrate W is greater than or equal to the threshold even after the flow of correcting the position of the substrate W and performing rescanning is repeated multiple times, the second transfer device 22B and the path placing part 26 may be abnormal. Therefore, the controller 90 may proceed to a process of notifying a user of the abnormality when the flow of correcting the position of the substrate W and performing rescanning is repeated a preset number of times.

Due to the above processing, the substrate W can be transferred by the second transfer device 22B such that the center position Wc of the substrate W placed on the path placing part 26 coincides with the reference position 223c of the fork 223 of the second transfer device 22B. In other words, the controller 90 sets the center position Wc of the substrate W as the transfer position of the path placing part 26, and updates the current transfer position of the path placing part 26 of the second transfer device 22B (step S108).

Accordingly, the controller 90 terminates the mode of the current teaching process of the second transfer device 22B (step S109). Further, in the substrate processing system 1, after the transfer teaching method of the second transfer device 22B is completed, the second transfer device 22B may operate based on the reset transfer position to receive the substrate W on the path placing part 26, and transfer the substrate W to an appropriate processing module 10. In this case, the substrate processing system 1 can detect the substrate W supported by the fork 223 using the processing module-side sensor 14, and determine whether or not the substrate W is accurately supported. Accordingly, the transfer state of the substrate W by the second transfer device 22B can be reconfirmed, which makes it possible to improve the transfer accuracy.

By performing the above-described transfer teaching method, in the substrate processing system 1, the substrate W can be accurately transferred by the second transfer device 22B during an operation in which the substrate W is actually transferred and subjected to substrate processing. Also when the substrate W supported by the second transfer device 22B is loaded into the processing module 10 from the path placing part 26, the position of the substrate W is detected by the processing module-side sensor 14, and the deviation of the substrate W is corrected. Therefore, in the substrate processing system 1, the substrate W can be more accurately loaded into the processing module 10.

Further, the technique of the present disclosure is not limited to the substrate processing system 1 and the transfer teaching method described above, and various modifications can be made. For example, in the transfer teaching method, an example in which the transfer position of the second transfer device 22B is corrected with respect to the substrate W transferred from the load-lock module 30 to the path placing part 26 by the first transfer device 22A has been described. However, the above-described transfer teaching method may be performed also in the case of transferring the substrate W from the processing module 10 in the front region 21A to the path placing part 26. This is because the substrate W may be deviated when it is transferred by the first transfer device 22A.

Further, the above-described transfer teaching method is not limited to the case where the substrate W is placed on the path placing part 26 by the second transfer device 22B. For example, when the second transfer device 22B places the substrate W on the placing table 12 of the processing module 10, the transfer position of the placed substrate W may be detected by the fork-side sensors 227, and the transfer position of the substrate W in the processing module 10 may be corrected based on the detection information.

Alternatively, the above-described transfer teaching method may be applied to the case of correcting the transfer position in the first transfer device 22A or the atmospheric transfer device 42. For example, when the first transfer device 22A unloads the substrate W from the load-lock module 30, the transfer position of the substrate W may be corrected by the above-described transfer teaching method. Further, when the second transfer device 22B takes out the substrate W from the processing module 10 and places the substrate W on the path placing part 26, the first transfer device 22A may correct the transfer position of the substrate W using the above-described transfer teaching method. Further, when the first transfer device 22A places the substrate W on the placing table 12 of the processing module 10, the transfer position of the placed substrate W may be detected by the fork-side sensors 227, and the transfer position of the substrate W in the processing module 10 may be corrected based on the detection information.

Hence, the substrate processing system 1 may have a configuration in which the vacuum transfer module 20 includes one vacuum transfer device 22 (the first transfer device 22A) and does not include the rear region 21B or the path region 25.

Further, in the substrate processing system 1, the objects to be transferred by the vacuum transfer device 22 or the atmospheric transfer device 42 is not limited to the substrate W, and may be another object. For example, the transfer object may be a ring R (see FIG. 1) disposed to surround the substrate W.

The technical ideas and effects of the present disclosure described in the above embodiments will be described below.

According to a first aspect of the present disclosure, the transfer teaching method for teaching the transfer position of the transfer device (the vacuum transfer device 22) to transfer the transfer object (the substrate W) using the transfer device includes: (A) moving the transfer device to the transfer object placed on the placing location (the path placing part 26) and detecting the transfer object using the sensor (the fork-side sensor 227) of the transfer device; (B) calculating the position of the transfer object based on the detected transfer object; and (C) setting the transfer position based on the calculated position of the transfer object.

In accordance with the above description, in the transfer teaching method, the position of the transfer object (the substrate W) placed on the placing location is calculated using the sensor (the fork-side sensor 227) of the transfer device (the vacuum transfer device 22), so that the position of the transfer object on the placing location can be recognized instead of the position of the placing location itself. Since the position of the transfer object includes the deviation of the transfer object, the transfer position is set to eliminate the deviation, which makes it possible to appropriately support and transfer the transfer object. As a result, the transfer teaching method can efficiently teach the transfer position, and can remarkably improve the transfer accuracy of the transfer object.

Further, in step (B), the deviation between the calculated position of the transfer object (substrate W) and the set position is calculated, and the position of the transfer device (the vacuum transfer device 22) is corrected based on the calculated deviation. After the correction, steps (A) and (B) are performed again to recalculate the position of the transfer object. Accordingly, the transfer teaching method can further improve the transfer accuracy of the transfer object.

Further, the transfer teaching method includes, after step (B), a step of comparing the deviation amount of the transfer object (the substrate W) with a threshold. If the deviation amount is greater than or equal to the threshold, the position of the transfer device (the transfer device 22) is corrected based on the calculated deviation. After the correction, steps (A) and (B) are performed again to recalculate the position of the transfer object. On the other hand, if the deviation amount is less than the threshold, step (C) is performed. Accordingly, in the transfer teaching method, when the deviation of the transfer object is less than the threshold, the transfer position can be smoothly set, and the teaching of the transfer position can be performed more efficiently.

Further, in step (A), the outer edge of the transfer object (the substrate W) is detected by the sensor (the fork-side sensor 227), and in step (B), the center position Wc of the transfer object is calculated, as the position of the transfer object, based on the detected outer edge of the transfer object. The transfer teaching method can easily monitor the deviation of the transfer object by calculating the center position Wc of the transfer object.

Further, in step (A), a plurality of locations on the outer edge of the transfer object placed on the placing location are detected by the sensor (the fork-side sensor 227) while moving the transfer device (the vacuum transfer device 22) linearly at a position vertically above the transfer object (the substrate W). In step (B), the center position Wc of the transfer object is calculated from the plurality of detected locations on the outer edge of the transfer object. Accordingly, the transfer teaching method can accurately obtain the center position Wc of the substrate W.

Further, in the vacuum transfer module 20 including the transfer chamber 21 that can be depressurized to a vacuum atmosphere, and the transfer device (the vacuum transfer device 22) that is disposed in the transfer chamber 21 and configured to transfer the transfer object (the substrate W), steps (A) to (C) are performed. Accordingly, the transfer teaching method can accurately set the transfer position in the vacuum transfer module 20.

Further, the transfer chamber 21 includes the plurality of transfer devices (the vacuum transfer devices 22), and the path region 25 in which the transfer object (the substrate W) is temporarily placed is provided between the plurality of transfer devices. Steps (A) to (C) are performed for at least one of the transfer devices. Accordingly, also in the system having the plurality of vacuum transfer devices 22, the transfer position can be set accurately.

Further, the plurality of transfer devices (the vacuum transfer devices 22) include the first transfer device 22A for loading the transfer object (the substrate W) into the transfer chamber 21 from the load-lock module 30, and the second transfer device 22B that is more distant from the load-lock modules 30 than the first transfer device 22A and the path region 25. Steps (A) to (C) are performed when the transfer position of the second transfer device 22B with respect to the transfer object, which is placed in the path region 25 by the first transfer device 22A, is set. Hence, when the second transfer device 22B receives the transfer object in the path region 25, it is possible to accurately support and transfer the transfer object.

Further, the transfer object is the substrate W that is transferred by the transfer device (the vacuum transfer device 22) and then subjected to substrate processing. Accordingly, the transfer teaching method can accurately set the transfer position of the substrate W.

The transfer device (the vacuum transfer device 22) includes the fork 223 on which the transfer object (the substrate W) is placed, and the plurality of arms 222 for moving the fork 223. The sensor (the fork-side sensor 227) is a displacement sensor that is disposed at the fork 223 and measures the distance to the transfer object opposed thereto. Accordingly, the transfer teaching method can stably detect (scan) the transfer object as the transfer device moves.

Further, the pair of sensors (the fork-side sensors 227) are disposed at the tip end of the fork 223, and are arranged at an interval smaller than the outer shape of the transfer object (the substrate W). Accordingly, the transfer teaching method can simply detect the transfer object using the pair of sensors.

Further, according to a second aspect of the present disclosure, the substrate processing system 1 includes the transfer chamber 21, the transfer device (the vacuum transfer device 22) disposed in the transfer chamber 21 and configured to transfer the transfer object (the substrate W), and the controller 90 configured to control the operation of the transfer device. The controller 90 controls, in the transfer teaching method for teaching the transfer position of the transfer device, (A) moving the transfer device with respect to the transfer object placed on the placing location (the path placing part 26) and detecting the transfer object using the sensor (the fork-side sensor 227) of the transfer device; (B) calculating the position of the transfer object based on the detected transfer object; and (C) setting a transfer position based on the calculated position of the transfer object. Also in this case, the substrate processing system 1 can efficiently teach the transfer position of the transfer device, and can remarkably improve the transfer accuracy of the transfer object.

The substrate processing system 1 and the transfer teaching method according to the embodiments of the present disclosure is illustrative in all respects and are not restrictive. The above-described embodiment may be changed or modified in various forms without departing from the scope of the appended claims and the gist thereof. The above-described embodiment may include other configurations without contradicting each other and may be combined without contradicting each other.

1. A transfer teaching method for teaching a transfer position of a transfer device to transfer a transfer object using the transfer device, the method comprising:
(A) moving the transfer device with respect to the transfer object placed on a placing location and detecting the transfer object using a sensor of the transfer device;
(B) calculating a position of the transfer object based on the detected transfer object; and
(C) setting the transfer position based on the calculated position of the transfer object.

2. The transfer teaching method of claim 1, wherein in said step (B), deviation between the calculated position of the transfer object and a set position is calculated, and
the position of the transfer device is corrected based on the calculated deviation, and the position of the transfer object is recalculated by performing said step (A) and said step (B) again after the correction.

3. The transfer teaching method of claim 2, further comprising, after said step (B), comparing a deviation amount of the transfer object with a threshold,
wherein if the deviation amount is greater than or equal to the threshold, the position of the transfer device is corrected based on the calculated deviation, and the position of the transfer object is recalculated by performing said step (A) and said step (B) again after the correction, and
if the deviation amount is less than the threshold, said step (C) is performed.

4. The transfer teaching method of claim 1, wherein in said step (A), an outer edge of the transfer object is detected by the sensor, and
in said step (B), a center position of the transfer object is calculated as the position of the transfer object based on the detected outer edge of the transfer object.

5. The transfer teaching method of claim 4, wherein in said step (A), a plurality of locations on the outer edge of the transfer object placed on the placing location are detected by the sensor while moving the transfer device linearly at a position vertically above the transfer object,
in said step (B), the center position of the transfer object is calculated from the plurality of detected locations on the outer edge of the transfer object.

6. The transfer teaching method of claim 1, wherein said steps (A) to (C) are performed in a vacuum transfer module including a transfer chamber that is depressurizable to a vacuum atmosphere, and the transfer device disposed in the transfer chamber and configured to transfer the transfer object.

7. The transfer teaching method of claim 6, wherein the transfer chamber includes a plurality of the transfer devices and a path region where the transfer object is temporarily placed between the plurality of transfer devices, and
said steps (A) to (C) are performed for at least one of the plurality of transfer devices.

8. The transfer teaching method of claim 7, wherein the plurality of transfer devices include a first transfer device for loading the transfer object from a load-lock module into the transfer chamber, and a second transfer device that is more distant from the load-lock module than the first transfer device and the path region, and
said steps (A) to (C) are performed when a transfer position of the second transfer device with respect to the transfer object, which is placed in the path region by the first transfer device, is set.

9. The transfer teaching method of claim 1, wherein the transfer object is a substrate that is transferred by the transfer device and then subjected to substrate processing.

10. The transfer teaching method of claim 1, wherein the transfer device includes a fork on which the transfer object is placed, and a plurality of arms configured to move the fork, and
the sensor is a displacement sensor that is disposed at the fork and measures a distance to the transfer object opposed thereto.

11. The transfer teaching method of claim 10, wherein a pair of the sensors are disposed at a tip end of the fork, and are arranged at an interval smaller than an outer shape of the transfer object.

12. A substrate processing system comprising:
a transfer chamber;
a transfer device disposed in the transfer chamber and configured to transfer a transfer object; and
a controller configured to control an operation of the transfer device,
wherein the controller controls, in a transfer teaching method for teaching a transfer position of the transfer device:
(A) moving the transfer device with respect to the transfer object placed on a placing location and detecting the transfer object using a sensor of the transfer device;
(B) calculating a position of the transfer object based on the detected transfer object; and
(C) setting the transfer position based on the calculated position of the transfer object.
